(19) United States
(12) Patent Application Publication
(10) Pub. No.: US 2003/0211244 A1
(43) Pub. Date: Nov. 13, 2003

(54) Reacting an organosilicon compound with an oxidizing gas to form an ultra low k dielectric

(75) Inventors: Lihua Li, San Jose, CA (US); Wen H. Zhu, Sunnyvale, CA (US); Tzu-Fang Huang, San Jose, CA (US); Li-Qun Xia, Santa Clara, CA (US); Ellie Y. Yieh, San Jose, CA (US); Son Van Nguyen, Los Gatos, CA (US); Lester A. D'Cruz, San Jose, CA (US); Troy Kim, Mountain View, CA (US); Dian Sugiarto, Sunnyvale, CA (US); Peter Wai-Man Lee, San Jose, CA (US); Hichem M'Saad, Santa Clara, CA (US); Melissa M. Tam, Fremont, CA (US); Yi Zheng, San Jose, CA (US); Srinivas D. Nemani, Sunnyvale, CA (US)

Correspondence Address: Patent Counsel, APPLIED MATERIALS, INC., P.O. Box 450A, Santa Clara, CA, 95052, US

(73) Assignee: Applied Materials, Inc.

(21) Appl. No.: 10/409,887

(22) Filed: Apr. 8, 2003

Related U.S. Application Data
(63) Continuation-in-part of application No. 10/121,284, filed on Apr. 11, 2002.

(51) Int. Cl. B05D 5/12; C23C 16/00; B05D 3/00

(52) U.S. Cl. 427/255.28; 427/551; 427/58

(57) ABSTRACT

A method for depositing a low dielectric constant film having a dielectric constant of about 3.0 or less, preferably about 2.5 or less, is provided by reacting a gas mixture including one or more organosilicon compounds and one or more oxidizing gases. In one aspect, the organosilicon compound comprises a hydrocarbon component having one or more unsaturated carbon-carbon bonds, and in another aspect, the gas mixture further comprises one or more aliphatic hydrocarbon compounds having one or more unsaturated carbon-carbon bonds. The low dielectric constant film is post-treated after it is deposited. In one aspect, the post treatment is an electron beam treatment, and in another aspect, the post-treatment is an annealing process.

### CROSS-REFERENCE TO RELATED APPLICATIONS

This application is a continuation-in-part of co-pending U.S. patent application Ser. No. 10/121,284, filed Apr. 11, 2002, which is herein incorporated by reference.

### BACKGROUND OF THE INVENTION

1. Field of the Invention

Embodiments of the present invention relate to the fabrication of integrated circuits. More particularly, embodiments of the present invention relate to a process for depositing dielectric layers on a substrate.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 0.13 μm and even 0.1 μm feature sizes, and tomorrow's facilities soon will be producing devices having even smaller feature sizes.

The continued reduction in device geometries has generated a demand for films having lower k values because the capacitive coupling between adjacent metal lines must be reduced to further reduce the size of devices on integrated circuits. In particular, insulators having low dielectric constants (k), less than about 4.0, are desirable. Examples of insulators having low dielectric constants include spin-on glass, such as un-doped silicon glass (USG) or fluorine-doped silicon glass (FSG), silicon dioxide, and polytetrafluoroethylene (PTFE), which are all commercially available.

More recently, organosilicon films having k values less than about 3.5 have been developed. In an attempt to further lower k values, Rose et al. (U.S. Pat. No. 6,068,884) disclosed a method for depositing an insulator by partially fragmenting a cyclic organosilicon compound to form both cyclic and linear structures in the deposited film. However, this method of partially fragmenting cyclic precursors is difficult to control and thus, product consistency is difficult to achieve.

There is a need, therefore, for a controllable process for making lower dielectric constant materials to improve the speed and efficiency of devices on integrated circuits.

### SUMMARY OF THE INVENTION

Embodiments of the invention include a method for depositing a low dielectric constant film having a dielectric constant of about 3.0 or less, preferably about 2.5 or less, by reacting one or more organosilicon compounds and one or more oxidizing gases. In one aspect, a cyclic organosilicon compound, an aliphatic organosilicon compound, and an aliphatic hydrocarbon compound are reacted with an oxidizing gas at conditions sufficient to deposit a low dielectric constant film on a semiconductor substrate. The cyclic organosilicon compound includes at least one silicon-carbon bond. The aliphatic organosilicon compound includes a silicon-hydrogen bond or a silicon-oxygen bond. In another aspect, an organosilicon compound and an aliphatic hydrocarbon compound are reacted with an oxidizing gas at conditions sufficient to deposit a low dielectric constant film on a semiconductor substrate. In one aspect, the aliphatic hydrocarbon includes at least one unsaturated carbon-carbon bond. In another aspect, an organosilicon compound having a hydrocarbon component having one or more unsaturated carbon-carbon bonds is reacted with an oxidizing gas at conditions sufficient to deposit a low dielectric constant film on a semiconductor substrate. The low dielectric constant film is post-treated after it is deposited. In one aspect, the film is post-treated with an electron beam treatment. In another aspect, the film is post-treated with an annealing process.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the description and appended drawings illustrate only typical embodiments of this invention and are therefore not to be considered limiting of its scope, for the invention may admit to other equally effective embodiments.

FIG. 1 is a cross-sectional diagram of an exemplary CVD reactor configured for use according to embodiments described herein.

FIG. 2 is a flow chart of a process control computer program product used in conjunction with the exemplary CVD reactor of FIG. 1.

FIG. 3 shows a relationship between dielectric constant and ratio of gases.

### DETAILED DESCRIPTION OF THE PREFERRED EMBODIMENTS

Embodiments of the invention include a significant and unexpected reduction in dielectric constants for films containing silicon, oxygen, and carbon by reacting one or more organosilicon compounds with one or more oxidizing gases at conditions sufficient to form an ultra low dielectric constant film (k less than 2.5). The ultra low dielectric constant film is preferably post-treated with an electron beam or an annealing process after it is deposited to obtain a lower dielectric constant.

The organosilicon compounds include cyclic organosilicon compounds having a ring structure and three or more silicon atoms. The ring structure may further comprise one or more oxygen atoms. Commercially available cyclic organosilicon compounds include rings having alternating silicon and oxygen atoms with one or two alkyl groups bonded to the silicon atoms. For example, the cyclic organosilicon compounds may include one or more of the following compounds:

| | |
|---|---|
| 1,3,5-trisilano-2,4,6-trimethylene, | ( SiH₂CH₂)₃ - |
| | (cyclic) |
| 1,3,5,7-tetramethylcyclotetrasiloxane (TMCTS) | ( SiHCH₃—O)₄ - |
| | (cyclic) |
| octamethylcyclotetrasiloxane (OMCTS), | ( Si(CH₃)₂—O)₄ - |
| | (cyclic) |
| 1,3,5,7,9-pentamethylcyclopentasiloxane, | ( SiHCH₃—O)₅ - |
| | (cyclic) |
| 1,3,5,7-tetrasilano-2,6-dioxy-4,8-dimethylene, | ( SiH₂—CH₂—SiH₂— |
| | O)₂ - (cyclic) |
| hexamethylcyclotrisiloxane | ( Si(CH₃)₂—O)₃ - |
| | (cyclic). |

The organosilicon compounds further include aliphatic organosilicon compounds having one or more silicon atoms and one or more carbon atoms. The structures may further comprise oxygen. Commercially available aliphatic organosilicon compounds include organosilanes that do not contain oxygen between silicon atoms and organosiloxanes that contain oxygen between two or more silicon atoms. For example, the aliphatic organosilicon compounds may include one or more of the following compounds:

| | |
|---|---|
| methylsilane, | CH₃—SiH₃ |
| dimethylsilane, | (CH₃)₂—SiH₂ |
| trimethylsilane, | (CH₃)₃—SiH |
| diethoxymethylsilane | (CH₃—CH₂—O)₂—SiH—CH₃ |
| dimethyldimethoxysilane, | (CH₃)₂—Si—(OCH₃)₂ |
| ethylsilane, | CH₃—CH₂—SiH₃ |
| disilanomethane, | SiH₃—CH₂—SiH₃ |
| bis(methylsilano)methane, | CH₃—SiH₂—CH₂—SiH₂—CH₃ |
| 1,2-disilanoethane, | SiH₃—CH₂—CH₂—SiH₃ |
| 1,2-bis(methylsilano)ethane, | CH₃—SiH₂—CH₂—CH₂—SiH₂—CH₃ |
| 2,2-disilanopropane, | SiH₃—C(CH₃)₂—SiH₃ |
| 1,3-dimethyidisiloxane, | CH₃—SiH₂—O—SiH₂—CH₃ |
| 1,1,3,3-tetramethyldisiloxane | (CH₃)₂—SiH—O—SiH—(CH₃)₂ |
| (TMDSO), | |
| hexamethyldisiloxane (HMDS), | (CH₃)₃—Si—O—Si—(CH₃)₃ |
| 1,3-bis(silanomethylene) | (SiH₃—CH₂—SiH₂—)₂—O |
| disiloxane | |
| bis(1-methyldisiloxanyl) | (CH₃—SiH₂—O—SiH₂—)₂—CH₂ |
| methane, | |
| 2,2-bis(1-methyldisiloxanyl) | (CH₃—SiH₂—O—SiH₂—)₂—C(CH₃)₂ |
| propane, | |
| hexamethoxydisiloxane | (CH₃O)₃—Si—O—Si—(OCH₃)₃ |
| (HMDS) | |
| diethylsilane | (C₂H₅)₂SiH₂, |
| propylsilane | C₃H₇SiH₃, |
| 1,1,2,2-tetramethyldisilane | HSi(CH₃)₂—Si(CH₃)₂H, |
| hexamethyldisilane | (CH₃)₃Si—Si(CH₃)₃, |
| 1,1,2,2,3,3- | H(CH₃)₂Si—Si(CH₃)₂—SiH(CH₃)₂, |
| hexamethyltrisilane | |
| 1,1,2,3,3- | H(CH₃)₂Si—SiH(CH₃)—SiH(CH₃)₂, |
| pentamethyltrisilane | |
| dimethyldisilanoethane | CH₃—SiH₂—(CH₂)₂—SiH₂—CH₃, |
| dimethyldisilanopropane | CH₃—SiH—(CH₂)₃—SiH—CH₃, |
| tetramethyldisilanoethane | (CH₃)₂—SiH—(CH₂)₂—SiH—(CH₃)₂, |
| tetramethyldisilanopropane | (CH₃)₂—Si—(CH₂)₃—Si—(CH₃)₂. |

The organosilicon compounds further include organosilicon compounds having a hydrocarbon component having one or more unsaturated carbon-carbon bonds, such as carbon-carbon double bonds, carbon-carbon triple bonds, or aromatic groups. For example, the organosilicon compounds having a hydrocarbon component having one or more unsaturated carbon-carbon bonds may include one or more of the following compounds:

| | |
|---|---|
| vinylmethylsilane | CH₂=CHSiH₂CH₃, |
| dimethoxymethylvinylsilane | (CH₃O)₂—Si(CH₃)—CH=CH₂, |
| (DMMVS) | |
| trimethylsilylacetylene | (CH₃)₃Si—C≡CH, |
| 1-(trimethylsilyl)-1,3-butadiene | (CH₃)₃Si—HC≡CH—HC≡CH₂, |
| trimethylsilylcyclopentadiene | (CH₃)₃Si—C₅H₅, |
| trimethylsilylacetate | (CH₃)₃Si—O(C=O)CH₃, |
| di-tertbutoxydiacetoxysilane | ((CH₃)₃(C=O))₂—Si—((C=O)(CH₃)₃)₂. |

In one embodiment, one or more organosilicon compounds having a hydrocarbon component having one or more unsaturated carbon-carbon bonds is reacted with one or more oxidizing gases and delivered to a substrate surface at conditions sufficient to deposit a low dielectric constant film on the substrate.

In another embodiment, one or more organosilicon compounds and one or more aliphatic hydrocarbons are reacted with one or more oxidizing gases and delivered to a substrate surface at conditions sufficient to deposit a low dielectric constant film on the substrate. The aliphatic hydrocarbon compounds may include between one and about 20 adjacent carbon atoms. The hydrocarbon compounds can include adjacent carbon atoms that are bonded by any combination of single, double, and triple bonds. Preferably, the aliphatic hydrocarbon compounds include at least one unsaturated carbon-carbon bond. For example, the aliphatic compounds may include alkenes, alkylenes, and dienes having two to about 20 carbon atoms, such as ethylene, propylene, isobutylene, acetylene, allylene, ethylacetylene, 1,3-butadiene, isoprene, 2,3-dimethyl-1,3-butadiene, and piperylene.

In any of the embodiments described herein, the one or more oxidizing gases may include oxygen (O₂), ozone (O₃), nitrous oxide (N₂O), carbon monoxide (CO), carbon dioxide (CO₂), water (H₂O), hydrogen peroxide (H₂O₂), or combinations thereof. In one aspect, the oxidizing gas is oxygen gas. In another aspect, the oxidizing gas is ozone. When ozone is used as an oxidizing gas, an ozone generator converts from 6% to 20%, typically about 15%, by weight of the oxygen in a source gas to ozone, with the remainder typically being oxygen. Yet, the ozone concentration may be increased or decreased based upon the amount of ozone desired and the type of ozone generating equipment used. The one or more oxidizing gases are added to the reactive gas mixture to increase reactivity and achieve the desired carbon content in the deposited film.

The films contain a carbon content between about 5 and about 30 atomic percent (excluding hydrogen atoms), preferably between about 5 and about 20 atomic percent. The carbon content of the deposited films refers to atomic analysis of the film structure which typically does not contain significant amounts of non-bonded hydrocarbons. The carbon contents are represented by the percent of carbon atoms in the deposited film, excluding hydrogen atoms which are difficult to quantify. For example, a film having an average of one silicon atom, one oxygen atom, one carbon atom, and two hydrogen atoms has a carbon content of 20 atomic percent (one carbon atom per five total atoms), or a carbon content of 33 atomic percent excluding hydrogen atoms (one carbon atom per three total atoms).

In any of the embodiments described herein, after the low dielectric constant film is deposited, the film may be treated with an electron beam (e-beam) to reduce the dielectric constant of the film. The electron beam treatment typically has a dose between about 50 and about 2000 micro coulombs per square centimeter (μc/cm²) at about 1 to 20 kiloelectron volts (KeV). The e-beam treatment is typically operated at a temperature between about room-temperature and about 450° C. for about 1 minute to about 15 minutes, such as about 2 minutes. Preferably, the e-beam treatment is performed at about 400° C. for about 2 minutes. In one aspect, the e-beam treatment conditions include 4.5 kV, 1.5 mA and 500 μc/cm² at 400° C. Argon or hydrogen may be present during the electron beam treatment. Although any e-beam device may be used, one exemplary device is the EBK chamber, available from Applied Materials, Inc. Treating the low dielectric constant film with an electron beam after the low dielectric constant film is deposited will volatilize at least some of the organic groups in the film, forming voids in the film. Organic groups that may be volatilized are derived from organic components of the precursors described herein, such as the hydrocarbon component of the organosilicon compounds having a hydrocarbon component having one or more unsaturated carbon-carbon bonds, or the aliphatic hydrocarbons described herein. It is believed that forming voids in the film lowers the dielectric constant of the film. Preferably, the film is not deposited at a temperature greater than 150° C., as it is believed that higher temperatures will prevent sufficient incorporation into the film of organic groups that will be volatilized.

Alternatively, in another embodiment, after the low dielectric constant film is deposited, the film is post-treated with an annealing process to reduce the dielectric constant of the film. For example, films deposited by reacting one or more organosiloxanes or one or more oxygen-free organosilicon compounds with a gas mixture that includes an oxidizing gas may be post-treated with an annealing process. Preferably, the film is annealed at a temperature between about 200° C. and about 400° C. for about 2 seconds to about 1 hour, preferably about 30 minutes. A non-reactive gas such as helium, hydrogen, nitrogen, or a mixture thereof is introduced at a rate of 100 to about 10,000 sccm. The chamber pressure is maintained between about 2 Torr and about 10 Torr. The RF power is about 200 W to about 1,000 W at a frequency of about 13.56 MHz, and the preferable substrate spacing is between about 300 mils and about 800 mils.

Annealing the low dielectric constant film at a substrate temperature of about 200° C. to about 400° C. after the low dielectric constant film is deposited at a temperature of about 100° C. to about 150° C. will volatilize at least some of the organic groups in the film, forming voids in the film. Organic groups that may be volatilized are derived from organic components of the precursors described herein, such as the hydrocarbon component of the organosilicon compounds having a hydrocarbon component having one or more unsaturated carbon-carbon bonds, or the aliphatic hydrocarbons described herein. It is believed that forming voids in the film lowers the dielectric constant of the film. Preferably, the film is not deposited at a temperature greater than 150° C., as it is believed that higher temperatures will prevent sufficient incorporation into the film of organic groups that will be volatilized.

One or more meta-stable compounds may be added to the mixtures described above to further reduce the dielectric constant of the deposited film. The meta-stable compound first forms an unstable component within the film and then is removed from the film when the film is annealed. The removal of the unstable component during the anneal treatment forms a void within the film resulting in a significantly lower dielectric constant. The meta-stable compound is also known as a “leaving group” because of the nature of the process whereby the meta-stable compound leaves the film to form one or more voids therein. Exemplary meta-stable compounds may include t-butylethylene, 1,1,3,3-tetramethylbutylbenzene, t-butylether, methyl-methacrylate (MMA), and t-butylfurfurylether.

The anneal treatment removes the meta-stable component from the film as well as reduces a moisture content of the film. Moisture content may arise due to exposure to ambient air or by-product formation, for example.

Optionally, a second in-situ post treatment may be performed whereby the film is subjected to a temperature between about 100° C. and about 400° C. for about 2 seconds to about 10 minutes, preferably about 30 seconds. Helium, hydrogen, or a mixture thereof is flowed into the chamber at a rate of about 200 to about 10,000 sccm. The chamber pressure is maintained between about 2 Torr and about 10 Torr. The RF power is about 200 W to about 800 W at a frequency of about 13.56 MHz, and the preferable substrate spacing is between about 300 mils and about 800 mils. Preferably, the film is treated in one cycle using hydrogen gas.

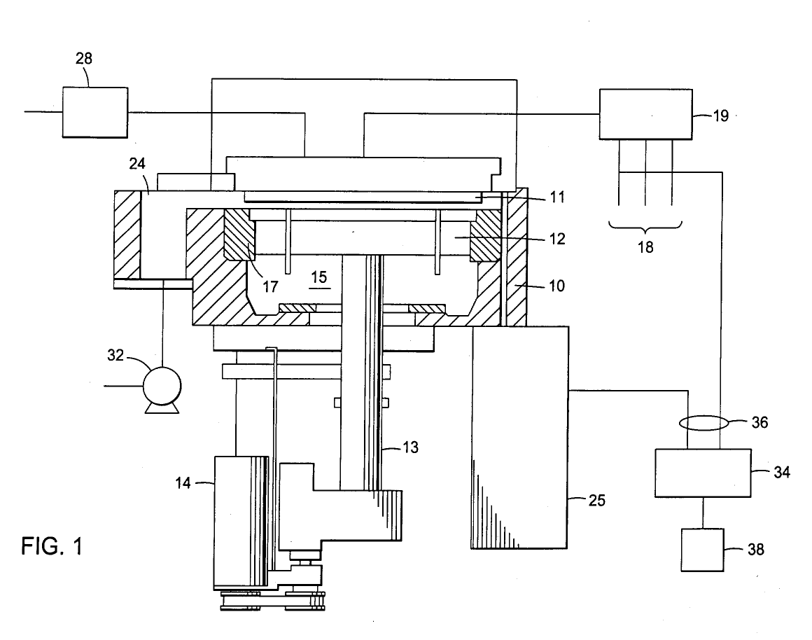

The film may be deposited using any processing chamber capable of chemical vapor deposition (CVD). For example, FIG. 1 shows a vertical, cross-section view of a parallel plate CVD processing chamber 10. The chamber 10 includes a high vacuum region 15 and a gas distribution manifold 11 having perforated holes for dispersing process gases there-through to a substrate (not shown). The substrate rests on a substrate support plate or susceptor 12. The susceptor 12 is mounted on a support stem 13 that connects the susceptor 12 to a lift motor 14. The lift motor 14 raises and lowers the susceptor 12 between a processing position and a lower, substrate-loading position so that the susceptor 12 (and the substrate supported on the upper surface of susceptor 12) can be controllably moved between a lower loading/off-loading position and an upper processing position which is closely adjacent to the manifold 11. An insulator 17 surrounds the susceptor 12 and the substrate when in an upper processing position.

Gases introduced to the manifold 11 are uniformly distributed radially across the surface of the substrate. A vacuum pump 32 having a throttle valve controls the exhaust rate of gases from the chamber 10 through a manifold 24. Deposition and carrier gases, if needed, flow through gas lines 18 into a mixing system 19 and then to the manifold 11. Generally, each process gas supply line 18 includes (i) safety shut-off valves (not shown) that can be used to automatically or manually shut off the flow of process gas into the chamber, and (ii) mass flow controllers (also not shown) to measure the flow of gas through the gas supply lines 18. When toxic gases are used in the process, several safety shut-off valves are positioned on each gas supply line 18 in conventional configurations.

During deposition in one embodiment, a blend/mixture of one or more organosilicon compounds and one or more aliphatic hydrocarbon compounds is reacted with an oxidizing gas to form an ultra low k film on the substrate. Preferably, a cyclic organosilicon compound is combined with at least one aliphatic organosilicon compound and at least one aliphatic hydrocarbon compound. For example, the mixture contains about 5 percent by volume to about 80 percent by volume of the one or more cyclic organosilicon compounds, about 5 percent by volume to about 15 percent by volume of the one or more aliphatic organosilicon compounds, and about 5 percent by volume to about 45 percent by volume of the one or more aliphatic hydrocarbon compounds. The mixture also contains about 5 percent by volume to about 20 percent by volume of the one or more oxidizing gases. More preferably, the mixture contains about 45 percent by volume to about 60 percent by volume of one or more cyclic organosilicon compounds, about 5 percent by volume to about 10 percent by volume of one or more aliphatic organosilicon compounds, and about 5 percent by volume to about 35 percent by volume of one or more aliphatic hydrocarbon compounds.

In one aspect, the one or more cyclic organosilicon compounds are introduced to the mixing system 19 at a flowrate of about 100 to about 10,000 sccm, preferably about 520 sccm. The one or more aliphatic hydrocarbon compounds are introduced to the mixing system 19 at a flowrate of about 100 to about 10,000 sccm, preferably 2,000 sccm. The oxygen containing gas has a flowrate between about 100 and about 6,000 sccm, preferably 1,000 sccm. One or more aliphatic organosilicon compounds may be introduced to the mixing system 19 at a flowrate of about 100 to about 1,000 sccm, preferably about 600 sccm. One or more organosilicon compounds having a hydrocarbon component having one or more unsaturated carbon-carbon bonds may be introduced to the mixing system 19 at a flowrate of about 100 sccm to about 10,000 sccm. Preferably, the cyclic organosilicon compound is 1,3,5,7-tetramethylcyclotetrasiloxane, octamethylcyclotetrasiloxane, or a mixture thereof, and the aliphatic organosilicon compound is trimethylsilane, 1,1,3,3-tetramethyidisiloxane, or a mixture thereof. The aliphatic hydrocarbon compound is preferably ethylene.

In another aspect, the aliphatic hydrocarbons include one or more meta-stable precursors. The one or more meta-stable precursors are added in amounts of about 100 sccm to about 5,000 sccm. Preferably, the meta-stable organic precursor is t-butylether.

The deposition process can be either a thermal process or a plasma enhanced process. In a plasma enhanced process, a controlled plasma is typically formed adjacent the substrate by RF energy applied to the gas distribution manifold 11 using a RF power supply 25. Alternatively, RF power can be provided to the susceptor 12. The RF power to the deposition chamber may be cycled or pulsed to reduce heating of the substrate and promote greater porosity in the deposited film. The power density of the plasma for a 200 mm substrate is between about 0.03 W/cm² and about 3.2 W/cm², which corresponds to a RF power level of about 10 W to about 2,000 W. Preferably, the RF power level is between about 300 W and about 1,700 W.

The RF power supply 25 can supply a single frequency RF power between about 0.01 MHz and 300 MHz. Alternatively, the RF power may be delivered using mixed, simultaneous frequencies to enhance the decomposition of reactive species introduced into the high vacuum region 15. In one aspect, the mixed frequency is a lower frequency of about 12 kHz and a higher frequency of about 13.56 mHz. In another aspect, the lower frequency may range between about 300 Hz to about 1,000 kHz, and the higher frequency may range between about 5 mHz and about 50 mHz.

During deposition, the substrate is maintained at a temperature between about −20° C. and about 500° C., preferably between about 100° C. and about 450° C., more preferably between about 100° C. and about 150° C. For example, the substrate may be maintained at about 125° C. The deposition pressure is typically between about 1 Torr and about 20 Torr, preferably between about 4 Torr and about 7 Torr. The deposition rate is typically between about 10,000 Å/min and about 20,000 Å/min.

When additional dissociation of the oxidizing gas is desired, an optional microwave chamber 28 can be used to input power from between about 50 Watts and about 6,000 Watts to the oxidizing gas prior to the gas entering the processing chamber 10. The additional microwave power can avoid excessive dissociation of the organosilicon compounds prior to reaction with the oxidizing gas. A gas distribution plate (not shown) having separate passages for the organosilicon compound and the oxidizing gas is preferred when microwave power is added to the oxidizing gas.

Typically, any or all of the chamber lining, distribution manifold 11, susceptor 12, and various other reactor hardware is made out of materials such as aluminum or anodized aluminum. An example of such a CVD reactor is described in U.S. Pat. No. 5,000,113, entitled “A Thermal CVD/PECVD Reactor and Use for Thermal Chemical Vapor Deposition of Silicon Dioxide and In-situ Multi-step Planarized Process,” which is incorporated by reference herein.

A system controller 34 controls the motor 14, the gas mixing system 19, and the RF power supply 25 which are connected therewith by control lines 36. The system controller 34 controls the activities of the CVD reactor and typically includes a hard disk drive, a floppy disk drive, and a card rack. The card rack contains a single board computer (SBC), analog and digital input/output boards, interface boards, and stepper motor controller boards. The system controller 34 conforms to the Versa Modular Europeans (VME) standard which defines board, card cage, and connector dimensions and types. The VME standard also defines the bus structure having a 16-bit data bus and 24-bit address bus.

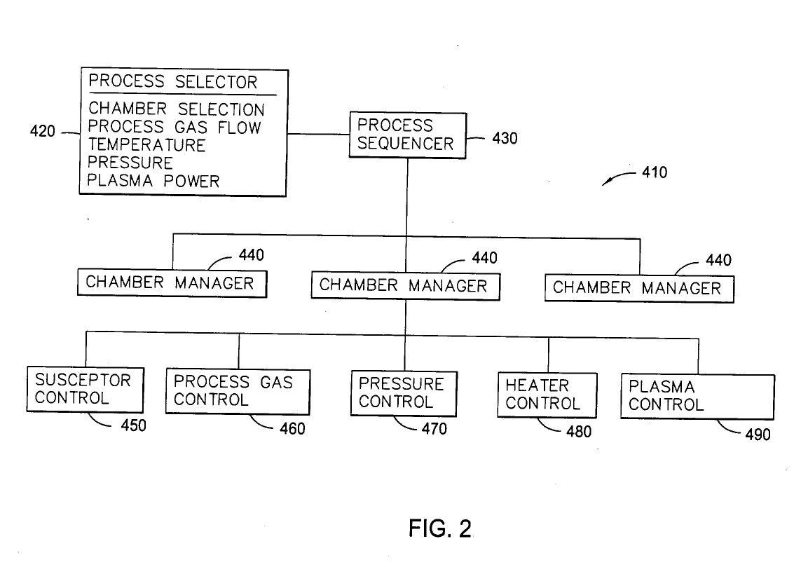

FIG. 2 shows an illustrative block diagram of a hierarchical control structure of a computer program 410. The system controller 34 operates under the control of the computer program 410 stored on a hard disk drive 38. The computer program 410 dictates the timing, mixture of gases, RF power levels, susceptor position, and other parameters of a particular process. The computer program code can be written in any conventional computer readable programming language such as, for example, 68000 assembly language, C, C++, or Pascal. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled windows library routines. To execute the linked compiled object code, the system user invokes the object code, causing the computer system to load the code in memory, from which the CPU reads and executes the code to perform the tasks identified in the program.

A user enters a process set number and process chamber number into a process selector subroutine 420 in response to menus or screens displayed on the CRT monitor by using a light pen interface. The process sets are predetermined sets of process parameters necessary to carry out specified processes, and are identified by predefined set numbers. The process selector subroutine 420 (i) selects a desired process chamber on the cluster tool, and (ii) selects a desired set of process parameters needed to operate the process chamber for performing the desired process. The process parameters for performing a specific process are provided to the user in the form of a recipe and relate to process conditions such as, for example, process gas composition, flow rates, temperature, pressure, plasma conditions such as RF bias power levels and magnetic field power levels, cooling gas pressure, and chamber wall temperature. The parameters specified by the recipe are entered utilizing the light pen/CRT monitor interface. The signals for monitoring the process are provided by the analog input and digital input boards of the system controller 34 and the signals for controlling the process are output to the analog output and digital output boards of the system controller 34.

A process sequencer subroutine 430 comprises program code for accepting the identified process chamber and set of process parameters from the process selector subroutine 420, and for controlling operation of the various process chambers. Multiple users can enter process set numbers and process chamber numbers, or a user can enter multiple process chamber numbers, so the sequencer subroutine 430 operates to schedule the selected processes in the desired sequence. Preferably the sequencer subroutine 430 includes computer readable program code to perform the steps of (i) monitoring the operation of the process chambers to determine if the chambers are being used, (ii) determining what processes are being carried out in the chambers being used, and (iii) executing the desired process based on availability of a process chamber and type of process to be carried out. Conventional methods of monitoring the process chambers can be used, such as polling. When scheduling a process execute, the sequencer subroutine 430 can be designed to take into consideration the present condition of the process chamber being used in comparison with the desired process conditions for a selected process, or the “age” of each particular user entered request, or any other relevant factor a system programmer desires to include for determining the scheduling priorities.

Once the sequencer subroutine 430 determines which process chamber and process set combination is going to be executed next, the sequencer subroutine 430 causes execution of the process set by passing the particular process set parameters to a chamber manager subroutine 440 which controls multiple processing tasks in a process chamber according to the process set determined by the sequencer subroutine 430. For example, the chamber manager subroutine 440 includes program code for controlling CVD process operations in the process chamber 10. The chamber manager subroutine 440 also controls execution of various chamber component subroutines that control operation of the chamber component necessary to carry out the selected process set. Examples of chamber component subroutines are susceptor control subroutine 450, process gas control subroutine 460, pressure control subroutine 470, heater control subroutine 480, and plasma control subroutine 490. Those having ordinary skill in the art would readily recognize that other chamber control subroutines can be included depending on what processes are desired to be performed in a processing chamber.

In operation, the chamber manager subroutine 440 selectively schedules or calls the process component subroutines in accordance with the particular process set being executed. The chamber manager subroutine 440 schedules the process component subroutines similarly to how the sequencer subroutine 430 schedules which process chamber and process set is to be executed next. Typically, the chamber manager subroutine 440 includes steps of monitoring the various chamber components, determining which components needs to be operated based on the process parameters for the process set to be executed, and causing execution of a chamber component subroutine responsive to the monitoring and determining steps.

Operation of particular chamber component subroutines will now be described with reference to FIG. 2. The susceptor control positioning subroutine 450 comprises program code for controlling chamber components that are used to load the substrate onto the susceptor 12, and optionally to lift the substrate to a desired height in the processing chamber 10 to control the spacing between the substrate and the gas distribution manifold 11. When a substrate is loaded into the processing chamber 10, the susceptor 12 is lowered to receive the substrate, and thereafter, the susceptor 12 is raised to the desired height in the chamber to maintain the substrate at a first distance or spacing from the gas distribution manifold 11 during the CVD process. In operation, the susceptor control subroutine 450 controls movement of the susceptor 12 in response to process set parameters that are transferred from the chamber manager subroutine 440.

The process gas control subroutine 460 has program code for controlling process gas compositions and flow rates. The process gas control subroutine 460 controls the open/close position of the safety shut-off valves, and also ramps up/down the mass flow controllers to obtain the desired gas flow rate. The process gas control subroutine 460 is invoked by the chamber manager subroutine 440, as are all chamber components subroutines, and receives from the chamber manager subroutine process parameters related to the desired gas flow rates. Typically, the process gas control subroutine 460 operates by opening the gas supply lines, and repeatedly (i) reading the necessary mass flow controllers, (ii) comparing the readings to the desired flow rates received from the chamber manager subroutine 440, and (iii) adjusting the flow rates of the gas supply lines as necessary. Furthermore, the process gas control subroutine 460 includes steps for monitoring the gas flow rates for unsafe rates, and activating the safety shut-off valves when an unsafe condition is detected.

In some processes, an inert gas such as helium or argon is put into the processing chamber 10 to stabilize the pressure in the chamber before reactive process gases are introduced. For these processes, the process gas control subroutine 460 is programmed to include steps for flowing the inert gas into the chamber 10 for an amount of time necessary to stabilize the pressure in the chamber, and then the steps described above would be carried out.

Additionally, when a process gas is to be vaporized from a liquid precursor, such as OMCTS for example, the process gas control subroutine 460 would be written to include steps for bubbling a carrier/delivery gas such as argon, helium, nitrogen, hydrogen, carbon dioxide, ethylene, or mixtures thereof, for example, through the liquid precursor in a bubbler assembly. The carrier gas typically has a flowrate between about 100 sccm to about 10,000 sccm, preferably 1,000 sccm.

For this type of process, the process gas control subroutine 460 regulates the flow of the delivery gas, the pressure in the bubbler, and the bubbler temperature in order to obtain the desired process gas flow rates. As discussed above, the desired process gas flow rates are transferred to the process gas control subroutine 460 as process parameters. Furthermore, the process gas control subroutine 460 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

The pressure control subroutine 470 comprises program code for controlling the pressure in the processing chamber 10 by regulating the size of the opening of the throttle valve in the exhaust pump 32. The size of the opening of the throttle valve is set to control the chamber pressure to the desired level in relation to the total process gas flow, size of the process chamber, and pumping set point pressure for the exhaust pump 32. When the pressure control subroutine 470 is invoked, the desired, or target pressure level is received as a parameter from the chamber manager subroutine 440. The pressure control subroutine 470 operates to measure the pressure in the processing chamber 10 by reading one or more conventional pressure manometers connected to the chamber, compare the measure value(s) to the target pressure, obtain PID (proportional, integral, and differential) values from a stored pressure table corresponding to the target pressure, and adjust the throttle valve according to the PID values obtained from the pressure table. Alternatively, the pressure control subroutine 470 can be written to open or close the throttle valve to a particular opening size to regulate the processing chamber 10 to the desired pressure.

The heater control subroutine 480 comprises program code for controlling the temperature of the heat modules or radiated heat that is used to heat the susceptor 12. The heater control subroutine 480 is also invoked by the chamber manager subroutine 440 and receives a target, or set point, temperature parameter. The heater control subroutine 480 measures the temperature by measuring voltage output of a thermocouple located in a susceptor 12, compares the measured temperature to the set point temperature, and increases or decreases current applied to the heat module to obtain the set point temperature. The temperature is obtained from the measured voltage by looking up the corresponding temperature in a stored conversion table, or by calculating the temperature using a fourth order polynomial. The heater control subroutine 480 gradually controls a ramp up/down of current applied to the heat module. The gradual ramp up/down increases the life and reliability of the heat module. Additionally, a built-in-fail-safe mode can be included to detect process safety compliance, and can shut down operation of the heat module if the processing chamber 10 is not properly set up.

The plasma control subroutine 490 comprises program code for setting the RF bias voltage power level applied to the process electrodes in the processing chamber 10, and optionally, to set the level of the magnetic field generated in the reactor. Similar to the previously described chamber component subroutines, the plasma control subroutine 490 is invoked by the chamber manager subroutine 440.

The pretreatment and method for forming a pretreated layer of the present invention is not limited to any specific apparatus or to any specific plasma excitation method. The above CVD system description is mainly for illustrative purposes, and other CVD equipment such as electrode cyclotron resonance (ECR) plasma CVD devices, induction-coupled RF high density plasma CVD devices, or the like may be employed. Additionally, variations of the above described system such as variations in susceptor design, heater design, location of RF power connections and others are possible. For example, the substrate could be supported and heated by a resistively heated susceptor.

### EXAMPLES

### Hypothetical Example 1

A low dielectric constant film is deposited on a 200 mm substrate from the following reactive gases at a chamber pressure of about 6 Torr and a substrate temperature of about 100° C.

Octamethylcyclotetrasiloxane (OMCTS), at about 520 sccm;

Ethylene, at about 2,000 sccm;

Oxygen, at about 1,000 sccm; and

Helium, at about 1,000 sccm

The substrate is positioned 1,050 mils from the gas distribution showerhead. A power level of about 1200 W at a frequency of 13.56 MHz is applied to the showerhead for plasma enhanced deposition of the film. After the low dielectric constant film is deposited, the substrate is treated with electron beam exposure at about 400° C. with about 50 μc/cm² dosage in an EBK chamber. Argon is introduced into the chamber at a rate of about 200 sccm. The chamber pressure is maintained at about 35 mTorr.

### Hypothetical Example 2

A low dielectric constant film is deposited on a 200 mm substrate from the following reactive gases at a chamber pressure of about 14 Torr and a substrate temperature of about 125° C.

Octamethylcyclotetrasiloxane (OMCTS), at about 210 sccm;

Diethoxymethylsilane, at about 600 sccm;

1,3-butadiene, at about 1,000 sccm;

Oxygen, at about 600 sccm; and

Helium, at about 800 sccm

The substrate is positioned 1,050 mils from the gas distribution showerhead. A power level of about 1200 W at a frequency of 13.56 MHz is applied to the showerhead for plasma enhanced deposition of the film. After the low dielectric constant film is deposited, the substrate is treated with electron beam exposure at about 400° C. with about 50 μc/cm² dosage in an EBK chamber. Argon is introduced into the chamber at a rate of about 200 sccm. The chamber pressure is maintained at about 35 mTorr.

### Hypothetical Example 3

A low dielectric constant film is deposited on a 200 mm substrate from the following reactive gases at a chamber pressure of about 6 Torr and a substrate temperature of about 125° C.

Octamethylcyclotetrasiloxane (OMCTS), at about 520 sccm;

Propylene, at about 2,000 sccm;

Oxygen, at about 1,000 sccm; and

Helium, at about 1,000 sccm

The substrate is positioned 1,050 mils from the gas distribution showerhead. A power level of about 800 W at a frequency of 13.56 MHz is applied to the showerhead for plasma enhanced deposition of the film. After the low dielectric constant film is deposited, the substrate is annealed at a temperature between about 200° C. and about 400° C. for about 30 minutes. A non-reactive gas such as helium, hydrogen, nitrogen, or a mixture thereof is introduced into the chamber at a rate of 100 to about 10,000 sccm. The chamber pressure is maintained between about 2 Torr and about 10 Torr. The RF power is about 200 W to about 1,000 W at a frequency of about 13.56 MHz, and the preferable substrate spacing is between about 300 mils and about 800 mils.

### Hypothetical Example 4

A low dielectric constant film is deposited on a 200 mm substrate from the following reactive gases at a chamber pressure of about 6 Torr and a substrate temperature of about 100° C.

1,3,5,7-tetramethylcyclotetrasiloxane (TMCTS), at about 700 sccm;

Diethoxymethylsilane, at about 600 sccm;

2,3-dimethyl-1,3-butadiene, at about 2,000 sccm;

Oxygen, at about 1,000 sccm; and

Helium, at about 1,000 sccm

The substrate is positioned 1,050 mils from the gas distribution showerhead. A power level of about 800 W at a frequency of 13.56 MHz is applied to the showerhead for plasma enhanced deposition of the film. After the low dielectric constant film is deposited, the substrate is annealed at a temperature between about 200° C. and about 400° C. for about 30 minutes. A non-reactive gas such as helium, hydrogen, nitrogen, or a mixture thereof is introduced into the chamber at a rate of 100 to about 10,000 sccm. The chamber pressure is maintained between about 2 Torr and about 10 Torr. The RF power is about 700 W to about 1,000 W at a frequency of about 13.56 MHz, and the preferable substrate spacing is between about 300 mils and about 800 mils.

### Hypothetical Example 5

A low dielectric constant film is deposited on a substrate from the following reactive gases at a chamber pressure of about 6 Torr and a substrate temperature of about 130° C.

Vinylmethylsilane, at about 600 sccm;

Oxygen, at about 800 sccm; and

Carbon dioxide, at about 4,800 sccm

The substrate is positioned 1,050 mils from the gas distribution showerhead. A power level of about 1200 W at a frequency of 13.56 MHz is applied to the showerhead for plasma enhanced deposition of the film. After the low dielectric constant film is deposited, the substrate is treated with electron beam exposure at about 400° C. with about 50 μc/cm² dosage in an EBK chamber. Argon is introduced into the chamber at a rate of about 200 sccm. The chamber pressure is maintained at about 35 mTorr.

### Hypothetical Example 6

A low dielectric constant film is deposited on a 300 mm substrate from the following reactive gases at a chamber pressure of about 6 Torr and a substrate temperature of about 130° C.

Octamethylcyclotetrasiloxane (OMCTS), at about 483 sccm;

Ethylene, at about 1,600 sccm;

Carbon dioxide, at about 4,800 sccm;

Oxygen, at about 800 sccm; and

Argon, at about 1,600 sccm

The substrate is positioned 1,050 mils from the gas distribution showerhead. A power level of about 800 W at a frequency of 13.56 MHz is applied to the showerhead for plasma enhanced deposition of the film. After the low dielectric constant film is deposited, the substrate is treated with electron beam exposure at about 400° C. and 1.5 mA with about 70 μc/cm² dosage in an EBK chamber.

The following examples illustrate low dielectric films of the present invention. The films were deposited using a chemical vapor deposition chamber that is part of an integrated processing platform. In particular, the films were deposited using a Producer® system, available from Applied Materials, Inc. of Santa Clara, Calif.

### Example 1

A low dielectric constant film was deposited on a 200 mm substrate from the following reactive gases at a chamber pressure of about 6 Torr and substrate temperature of about 400° C.

Octamethylcyclotetrasiloxane (OMCTS), at about 520 sccm;

Trimethylsilane (TMS), at about 200 sccm;

Ethylene, at about 2,000 sccm;

Oxygen, at about 1,000 sccm; and

Helium, at about 1,000 sccm

The substrate was positioned 1,050 mils from the gas distribution showerhead. A power level of about 800 W at a frequency of 13.56 MHz was applied to the showerhead for plasma enhanced deposition of the film. The film was deposited at a rate of about 12,000 Å/min, and had a dielectric constant (k) of about 2.54 measured at 0.1 MHz.

### Example 2

A low dielectric constant film was deposited on a 200 mm substrate from the following reactive gases at a chamber pressure of about 6 Torr and substrate temperature of about 400° C.

Octamethylcyclotetrasiloxane (OMCTS), at about 520 sccm;

Trimethylsilane (TMS), at about 400 sccm;

Ethylene, at about 2,000 sccm;

Oxygen, at about 1,000 sccm; and

Helium, at about 1,000 sccm;

The substrate was positioned 1,050 mils from the gas distribution showerhead. A power level of about 800 W at a frequency of 13.56 MHz was applied to the showerhead for plasma enhanced deposition of the film. The film was deposited at a rate of about 12,000 Å/min, and had a dielectric constant (k) of about 2.51 measured at 0.1 MHz.

### Example 3

A low dielectric constant film was deposited on a 200 mm substrate from the following reactive gases at a chamber pressure of about 6 Torr and substrate temperature of about 400° C.

Octamethylcyclotetrasiloxane (OMCTS), at about 520 sccm;

Trimethylsilane (TMS), at about 600 sccm;

Ethylene, at about 2,000 sccm;

Oxygen, at about 1,000 sccm; and

Helium, at about 1,000 sccm

The substrate was positioned 1,050 mils from the gas distribution showerhead. A power level of about 800 W at a frequency of 13.56 MHz was applied to the showerhead for plasma enhanced deposition of the film. The film was deposited at a rate of about 12,000 Å/min, and had a dielectric constant (k) of about 2.47 measured at 0.1 MHz.

### Example 4

A low dielectric constant film was deposited on a 200 mm substrate from the following reactive gases at a chamber pressure of about 6 Torr and substrate temperature of about 400° C.

Octamethylcyclotetrasiloxane (OMCTS), at about 520 sccm;

Trimethylsilane (TMS), at about 800 sccm;

Ethylene, at about 2,000 sccm;

Oxygen, at about 1,000 sccm; and

Helium, at about 1,000 sccm

The substrate was positioned 1,050 mils from the gas distribution showerhead. A power level of about 800 W at a frequency of 13.56 MHz was applied to the showerhead for plasma enhanced deposition of the film. The film was deposited at a rate of about 12,000 Å/min, and had a dielectric constant (k) of about 2.47 measured at 0.1 MHz.

### Example 5

A low dielectric constant film was deposited on a 200 mm substrate from the following reactive gases at a chamber pressure of about 6 Torr and substrate temperature of about 400° C.

Octamethylcyclotetrasiloxane (OMCTS), at about 520 sccm;

Trimethylsilane (TMS), at about 900 sccm;

Ethylene, at about 2,000 sccm;

Oxygen, at about 1,000 sccm; and

Helium, at about 1,000 sccm

The substrate was positioned 1,050 mils from the gas distribution showerhead. A power level of about 800 W at a frequency of 13.56 MHz was applied to the showerhead for plasma enhanced deposition of the film. The film was deposited at a rate of about 12,000 Å/min, and had a dielectric constant (k) of about 2.48 measured at 0.1 MHz.

### Example 6

A low dielectric constant film was deposited on a substrate from the following reactive gases at a chamber pressure of about 14 Torr and substrate temperature of 350° C.

Octamethylcyclotetrasiloxane (OMCTS), at about 210 sccm;

Trimethylsilane (TMS), at about 400 sccm;

Oxygen, at about 600 sccm; and

Helium, at about 800 sccm

The substrate was positioned 450 mils from the gas distribution showerhead. A power level of 800 W at a frequency of 13.56 MHz was applied to the showerhead for plasma enhanced deposition of the film. The deposited film had a dielectric constant (k) of about 2.67 measured at 0.1 MHz.

### Example 7

A low dielectric constant film was deposited on a substrate from the following reactive gases at a chamber pressure of about 6 Torr and substrate temperature of 400° C.

Octamethylcyclotetrasiloxane (OMCTS), at about 520 sccm;

Ethylene, at about 2,000 sccm;

Oxygen, at about 1,000 sccm; and

Helium, at about 1,000 sccm

The substrate was positioned 1,050 mils from the gas distribution showerhead. A power level of 800 W at a frequency of 13.56 MHz was applied to the showerhead for plasma enhanced deposition of the film. The deposited film had a dielectric constant (k) of about 2.55 measured at 0.1 MHz.

### Example 8

A low dielectric constant film was deposited on a substrate from the following reactive gases at a chamber pressure of about 6 Torr and substrate temperature of 130° C.

Octamethylcyclotetrasiloxane (OMCTS), at about 483 sccm;

Ethylene, at about 3200 sccm;

Oxygen, at about 800 sccm; and

Carbon dioxide, at about 4800 sccm

The substrate was positioned 1050 mils from the gas distribution showerhead. A power level of about 1200 W at a frequency of 13.56 MHz was applied to the showerhead for plasma enhanced deposition of the film. After the low dielectric constant film was deposited, the substrate was treated with electron beam exposure at about 400° C. with about 50 μc/cm² dosage in an EBK chamber. Argon was introduced into the chamber at a rate of about 200 sccm. The chamber pressure was maintained at about 35 mTorr.

### Example 9

Low dielectric constant films were deposited on 300 mm substrates from the following reactive gases at a chamber pressure of about 5 Torr and substrate temperature of 400° C.

Octamethylcyclotetrasiloxane (OMCTS), at about 302 sccm;

Trimethylsilane, at about 600 sccm;

Oxygen, at about 600 sccm;

Ethylene, at about 1000 sccm; and

Helium, at about 1200 sccm

The substrates were positioned 350 mils from the gas distribution showerhead. A power level of about 800 W at a frequency of 13.56 MHz and a power level of about 250 W at a frequency of 356 kHz were applied for plasma enhanced deposition of the films. After the low dielectric constant films were deposited, the substrates were post-treated with helium. The films were deposited at a rate of 13,000 Å/min and had an average dielectric constant of about 2.97 to about 3.06. The average refractive index was 1.453. The hardness of the films was about 2.2 gPa, and the uniformity was less than 2%. The modulus was about 13.34. The leakage current was about 4.55×10⁻¹⁰ amp/cm² at 1 MV/cm. The leakage current was about 2.68×10⁻⁹ amp/cm² at 2 MV/cm. The breakdown voltage was about 5.93 MV/cm. The stress was about 4.00×10⁸ dynes/cm², and the cracking threshold was greater than 7 μm.

### Example 10

Low dielectric constant films were deposited on 200 mm substrates from the following reactive gases at a chamber pressure of about 4.5 Torr and substrate temperature of 400° C.

Octamethylcyclotetrasiloxane (OMCTS), at about 151 sccm;

Trimethylsilane, at about 300 sccm;

Oxygen, at about 300 sccm;

Ethylene, at about 500 sccm; and

Helium, at about 600 sccm

The substrates were positioned 350 mils from the gas distribution showerhead. A power level of about 400 W at a frequency of 13.56 MHz and a power level of about 150 W at a frequency of 356 kHz were applied for plasma enhanced deposition of the films. After the low dielectric constant films were deposited, the substrates were post-treated with hydrogen. The films were deposited at a rate of 10,000 Å/min and had an average dielectric constant of about 2.96 to about 3.01. The average refractive index was 1.454. The hardness of the films was about 2.03 to about 2.08 gPa, and the uniformity was 2.2%. The modulus was about 12.27. The leakage current was about 4.27×10⁻¹⁰ amp/cm² at 2 MV/cm. The leakage current was about 1.88×10⁻⁹ amp/cm² at 2 MV/cm. The breakdown voltage was about 4.31 MV/cm. The stress was about 5.40×10⁸ dynes/cm², and the cracking threshold was greater than 7 μm.

While Examples 9 and 10 use helium as a carrier gas, argon may also be used as the carrier gas. It is believed that the use of argon as a carrier gas increases the porosity of the deposited film and lowers the dielectric constant of the deposited film. It is believed that the use of argon and mixed frequency RF power increases the deposition rate of the films by improving the efficiency of precursor dissociation. Additionally, it is believed that the use of argon and mixed frequency RF power enhances the hardness and modulus strength of the films without increasing the dielectric constant of the films. Furthermore, it is believed that the use of argon and mixed frequency RF power reduces the beveled deposition of material that may occur at the edge of a substrate.

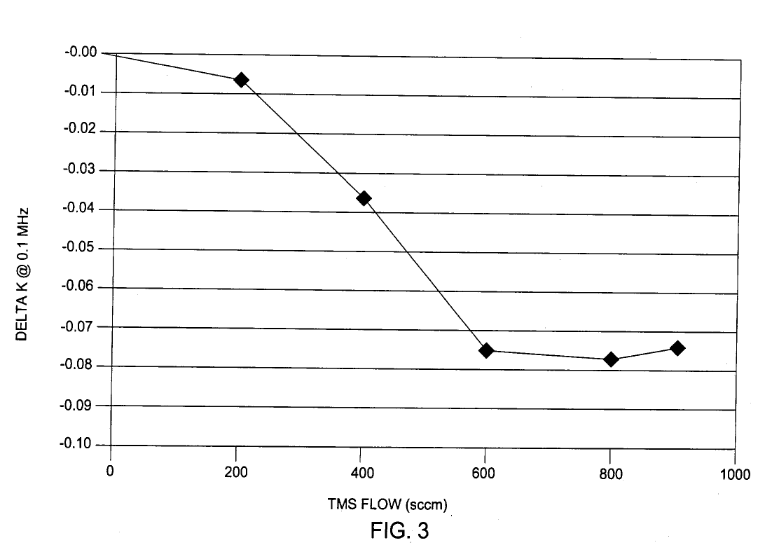

FIG. 3 illustrates the effect of varying the flow rate of TMS in Examples 1-5 described above. It was surprisingly found that the dielectric constant significantly decreased as the flow rate of TMS increased between about 200 sccm to about 600 sccm. The low dielectric constants were achieved with a ratio of aliphatic hydrocarbon compound to aliphatic organosilicon compound of about 15:1 to about 1:1. As illustrated with Example 6 and shown in FIG. 3, the addition of a sufficient amount of the aliphatic hydrocarbon compound to the cyclic organosilicon and aliphatic organosilicon compounds provided a dielectric constant at least 7% lower than a dielectric constant obtained by omitting the aliphatic hydrocarbon compound. Further, the addition of a sufficient amount of the aliphatic organosilicon compound to the cyclic organosilicon and aliphatic hydrocarbon compounds provided a dielectric constant about 3% lower than a dielectric constant obtained by omitting the aliphatic organosilicon compound as shown in Example 7.

While the foregoing is directed to preferred embodiments of the present invention, other and further embodiments of the invention may be devised without departing from the basic scope thereof, and the scope thereof is determined by the claims which follow.

What is claimed is:

1. A method for depositing a low dielectric constant film having a dielectric constant of about 3.0 or less, comprising:
reacting a gas mixture comprising:
one or more organosilicon compounds;
one or more aliphatic hydrocarbon compounds having one or more unsaturated carbon-carbon bonds; and
one or more oxidizing gases;
delivering the gas mixture to a substrate surface at conditions sufficient to deposit the low dielectric constant film on the substrate surface; and
post-treating the low dielectric constant film with an electron beam to reduce the dielectric constant of the film.

2. The method of claim 1, wherein the one or more organosilicon compounds comprises at least one silicon-carbon bond.

3. The method of claim 2, wherein the one or more organosilicon compounds further comprises a silicon-hydrogen bond.

4. The method of claim 1, wherein the aliphatic hydrocarbon compound comprises two or more unsaturated carbon-carbon bonds.

5. The method of claim 1, wherein the one or more organosilicon compounds is selected from the group consisting of 3,5-trisilano-2,4,6-trimethylene, 1,3,5,7-tetramethylcyclotetrasiloxane (TMCTS), octamethylcyclotetrasiloxane (OMCTS), 1,3,5,7,9-pentamethylcyclopentasiloxane, 1,3,5,7-tetrasilano-2,6-dioxy-4,8-dimethylene, and hexamethylcyclotrisiloxane.

6. The method of claim 5, wherein the one or more organosilicon compounds further comprises an aliphatic organosilicon compound.

7. The method of claim 1, wherein the organosilicon compound is selected from the group consisting of methylsilane, dimethylsilane, trimethylsilane, diethoxymethylsilane, dimethyldimethoxysilane, ethylsilane, disilanomethane, bis(methylsilano)methane, 1,2-disilanoethane, 1,2-bis(methylsilano)ethane, 2,2-disilanopropane, 1,3-dimethyldisiloxane, 1,1,3,3-tetramethyldisiloxane (TMDSO), hexamethyldisiloxane (HMDS), 1,3-bis(silanomethylene)disiloxane, bis(1-methyldisiloxanyl)methane, 2,2-bis(1-methyldisiloxanyl)propane, diethylsilane, propylsilane, vinylmethylsilane, 1,1,2,2-tetramethyldisilane, hexamethyldisilane, 1,1,2,2,3,3-hexamethyltrisilane, 1,1,2,3,3-pentamethyltrisilane, dimethyldisilanoethane, dimethyldisilanopropane, tetramethyldisilanoethane, and tetramethyldisilanopropane.

8. The method of claim 1, wherein the one or more aliphatic hydrocarbon compounds is selected from the group consisting of ethylene, propylene, isobutylene, acetylene, allylene, ethylacetylene, 1,3-butadiene, isoprene, 2,3-dimethyl-1,3-butadiene, and piperylene.

9. The method of claim 1, wherein the one or more organosilicon compounds is selected from the group consisting of 1,3,5,7-tetramethylcyclotetrasiloxane (TMCTS), octamethylcyclotetrasiloxane (OMCTS), and a mixture thereof.

10. The method of claim 9, wherein the one or more organosilicon compounds further comprises methylsilane, dimethylsilane, trimethylsilane, or a mixture thereof.

11. The method of claim 1, wherein the one or more aliphatic hydrocarbon compounds comprises ethylene.

12. The method of claim 1, wherein the conditions comprise a power density ranging from about 0.03 W/cm² to about 3.2 W/cm².

13. The method of claim 1, wherein the conditions comprise a substrate temperature of about 100° C. to about 150° C.

14. The method of claim 1, wherein the post-treating the low dielectric constant film with an electron beam volatilizes organic material in the low dielectric constant film.

15. The method of claim 1, wherein the conditions comprise mixed frequency RF power.

16. The method of claim 15, wherein the mixed frequency RF power comprises RF power having a frequency of 13.56 MHz and RF power having a frequency of 356 kHz.

17. The method of claim 15, wherein the gas mixture further comprises argon.

18. A method for depositing a low dielectric constant film having a dielectric constant of about 3.0 or less, comprising:
reacting a gas mixture comprising:
one or more organosiloxanes;
one or more aliphatic compounds comprising an unsaturated aliphatic hydrocarbon compound; and
one or more oxidizing gases;
delivering the gas mixture to a substrate surface at conditions sufficient to deposit the low dielectric constant film on the substrate surface; and
post-treating the film to reduce the dielectric constant of the film.

19. The method of claim 18, wherein the post-treating comprises annealing the film at a temperature between about 200° C. to about 400° C.

20. The method of claim 18, wherein the post-treating comprises an electron beam treatment.

21. The method of claim 18, wherein the one or more organosiloxanes comprises a cyclic siloxane.

22. The method of claim 21, wherein the cyclic siloxane is selected from the group consisting of 1,3,5,7-tetramethylcyclotetrasiloxane, octamethylcyclotetrasiloxane, 1,3,5,7,9-pentamethylcyclopentasiloxane, and hexamethylcyclotrisiloxane.

23. The method of claim 18, wherein the one or more organosiloxanes comprises a linear siloxane.

24. The method of claim 23, wherein the linear siloxane is selected from the group consisting of 1,3-dimethyldisiloxane, 1,1,3,3-tetramethyldisiloxane, hexamethyldisiloxane, 1,3-bis(silanomethylene)disiloxane, and hexamethoxydisiloxane.

25. The method of claim 18, wherein the conditions comprise mixed frequency RF power.

26. The method of claim 25, wherein the mixed frequency RF power comprises RF power having a frequency of 13.56 MHz and RF power having a frequency of 356 kHz.

27. The method of claim 25, wherein the gas mixture further comprises argon.

28. A method for depositing a low dielectric constant film having a dielectric constant of about 3.0 or less, comprising:
reacting a gas mixture comprising:
one or more organosilicon compounds selected from the group consisting of methylsilane, dimethylsilane, trimethylsilane, ethylsilane, disilanomethane, bis(methylsilano)methane, 1,2-disilanoethane, 1,2-bis(methylsilano)ethane, 2,2-disilanopropane, diethylsilane, propylsilane, 1,1,2,2-tetramethyldisilane, hexamethyldisilane, 1,1,2,2,3,3-hexamethyltrisilane, 1,1,2,3,3-pentamethyltrisilane, dimethyldisilanoethane, dimethyldisilanopropane, tetramethyldisilanoethane, tetramethyldisilanopropane, and 1,3,5-trisilano-2,4,6-trimethylene;
one or more aliphatic compounds comprising an unsaturated aliphatic hydrocarbon compound; and
one or more oxidizing gases;
delivering the gas mixture to a substrate surface at conditions sufficient to deposit the low dielectric constant film on the substrate surface; and
post-treating the film to reduce the dielectric constant of the film.

29. The method of claim 28, wherein the post-treating comprises annealing the film at a temperature between about 200° C. to about 400° C.

30. The method of claim 28, wherein the post-treating comprises an electron beam treatment.

31. A method for depositing a low dielectric constant film having a dielectric constant of about 3.0 or less, comprising:
reacting a gas mixture comprising:
one or more organosilicon compounds having a hydrocarbon component having one or more unsaturated carbon-carbon bonds; and
one or more oxidizing gases;
delivering the gas mixture to a substrate surface at conditions sufficient to deposit the low dielectric constant film on the substrate surface; and
post-treating the low dielectric constant film with an electron beam to reduce the dielectric constant of the film.

32. The method of claim 31, wherein the conditions comprise a substrate temperature of about 100° C. to about 150° C.

33. The method of claim 31, wherein the post-treating comprises annealing the film at a temperature between about 200° C. to about 400° C.

34. The method of claim 31, wherein the post-treating comprises an electron beam treatment.

35. The method of claim 31, wherein the post-treating volatilizes organic material in the low dielectric constant film.

36. The method of claim 31, wherein the one or more organosilicon compounds is selected from the group consisting of dimethoxymethylvinylsilane, vinylmethylsilane, trimethylsilylacetylene, 1-(trimethylsilyl)-1,3-trimethylsilylcyclopentadiene, trimethylsilylacetate, and di-tertbutoxydiacetoxysilane.
